(19) United States
(12) Patent Application Publication
(10) Pub. No.: US 2026/0099640 A1
(43) Pub. Date: Apr. 9, 2026

(54) GEOSPATIAL ANALYSIS OF CO-TRAVELING MOVING ENTITIES USING MODEL

(71) Applicant: Lovelace AI Inc., Pittsburgh, PA (US)

(72) Inventors: John Wong, Pittsburgh, PA (US); Andrew W. Moore, Pittsburgh, PA (US)

(21) Appl. No.: 19/081,721

(22) Filed: Mar. 17, 2025

Related U.S. Application Data
(60) Provisional application No. 63/703,491, filed on Oct. 4, 2024.

(51) Int. Cl. G06F 30/20

(52) U.S. Cl. CPC G06F 30/20

(57) ABSTRACT

Various example embodiments described herein provide for geospatial analysis of co-traveling moving entities (or co-traveling moving objects) using one or more models. In particular, some embodiments provide a system that implements a non-probabilistic model approach for geospatial analysis of co-traveling moving entities, where the system uses an algorithm to search for trajectories of moving entities that go near a query (e.g., selected or targeted moving entity of interest), and then scores those trajectories with a scoring function that can reward co-occurrence over multiple sightings (e.g., observation points), which can favor co-occurrences where the moving entities seem to be moving together.

### CROSS-REFERENCE TO RELATED APPLICATIONS

This application claims priority to and the benefit of U.S. Provisional Patent Application No. 63/703,491, entitled “GEOSPATIAL ANALYSIS OF CO-TRAVELING MOVING ENTITIES USING MODEL,” filed on Mar. Oct. 4, 2024, which is incorporated herein by reference in its entirety.

### TECHNICAL FIELD

The present disclosure relates generally to moving entities, and, more particularly, various embodiments described herein provide for systems, methods, techniques, instruction sequences, and devices for geospatial analysis of co-traveling moving entities (or co-traveling moving objects) using one or more models.

### BACKGROUND

The field of geospatial analytics has seen significant advancements in recent years, driven by the increasing availability of location data and the development of sophisticated computational techniques. Geospatial analytics involves the gathering, display, and manipulation of imagery, geosynchronous positional system (GPS), satellite photography, and historical data, which are tied to location-specific coordinates. This field has applications across various industries, including transportation, logistics, urban planning, environmental monitoring, and more.

### BRIEF DESCRIPTION OF DRAWINGS

In the drawings, which are not necessarily drawn to scale, like numerals may describe similar components in different views. To easily identify the discussion of any particular element or act, the most significant digit or digits in a reference number refer to the figure number in which that element is first introduced. Some embodiments are illustrated by way of example, and not limitation, in the figures of the accompanying drawings.

FIG. 1 is a diagrammatic representation of a networked environment in which an example geospatial co-traveling moving entity analysis system of various embodiments may be deployed.

FIG. 2 is a block diagram illustrating an example implementation of a geospatial co-traveling moving entity analysis system, according to various embodiments of the present disclosure.

FIG. 3, FIG. 4, and FIG. 5 illustrate examples of analyzing co-traveling moving entities using different models, according to various embodiments of the present disclosure.

FIG. 6 is a flowchart illustrating an example method for geospatial analysis of co-traveling moving entities (or co-traveling moving objects) using one or more models, according to various example embodiments of the present disclosure.

FIG. 7 is a block diagram showing a software architecture within which the present disclosure may be implemented, according to some examples.

FIG. 8 is a diagrammatic representation of a machine in the form of a computer system within which a set of instructions may be executed for causing the machine to perform any one or more of the methodologies discussed herein, in accordance with some examples.

### DETAILED DESCRIPTION

Advances in various areas of geospatial analysis with respect to one or more moving entities (or objects), such as different types of vehicles (e.g., ships, automotive vehicles, aircraft, etc.), could significantly enhance the capabilities of geospatial analysis systems and methodologies and can provide useful insights into understanding or predicting movements of one or more moving entities. For instance, traditional methods of trajectory prediction of a moving entity often rely on simple extrapolation techniques that may not account for complex patterns of movement or interactions with other static or moving entities.

Traditional geospatial analysis systems can have difficulty managing the connectedness of moving entity information, such as the relationships between entities or the association of entities with organizations. For example, determining (e.g., identifying) co-traveling moving entities, which spend part of their lives moving (e.g., traveling) close to each other at the same time, can be challenging. Determining co-traveling moving entities can have important use cases in intelligence analysis. For example, when a rogue ship is on a mission, chances are that the rogue ship is not traveling alone.

One or more various embodiments described herein address these and other deficiencies present in conventional geospatial analysis technologies with respect to analysis of co-traveling moving entities. In particular, some embodiments provide a system that implements a non-probabilistic model approach for geospatial analysis of co-traveling moving entities, where the system uses an algorithm to search for trajectories of moving entities that go near a query (e.g., selected or targeted moving entity of interest), and then scores those trajectories with a scoring function that can reward co-occurrence over multiple sightings (e.g., observation points), and that can favor co-occurrences where the moving entities seem to be moving together. For some example embodiments, a trajectory of a given moving entity is determined to be near a query if at least N=1 of its movements are within a fixed radius R from the query at the same time. The value of R can be adjustable based on the moving entity type (e.g., 10 km for ships). For various example embodiments, the scoring function comprises a heuristic. For example, suppose a voyage V=[p₁, p₂, . . . , pₙ] is a time-ordered array of proximities, where proximity p=(1, b, r) represents an event in which there were sightings of a pair of moving entities at the same time t. A sub-voyage can be defined as a time-consecutive subsequence of proximities in the voyage V, and a movement can be defined as a sub-voyage of length 2. Suppose further that there is a plurality of blue (b) moving entities and a single red (r) moving entity, where the blue moving entities are the moving entities we are searching over, and the red moving entity is the query (e.g., selected or targeted moving entity of interest). One of the blue and red positions (denoted b and r) must be true (as opposed to being interpolated). This means either the position of b or r must be directly observed (e.g. coming directly from the transponder), and not estimated based on the interpolation of preceding and succeeding positions. Based on the foregoing, the scoring function score(V) can be defined to be the minimum weighted sum squared errors between the blue and red positions among all possible sub-voyages of V with length L=4. This is expressed by Equation 1 as follows:

$$score ( V ) = {min}_{s} score ( {p}_{s} , {p}_{s + 1} , … , {p}_{s + L - 1} ) = {min}_{s} ( \frac{1}{w} {\sum }_{i = s}^{s + L - 1} {error ( {b}_{i} , {r}_{i} )}^{2} )$$

In Equation 1, the weighting factor w can be the distance traveled by either blue moving entities or the red moving entity during the sub-voyage (whichever is smaller). In this way, if the period of co-occurrence is spread out spatially, then the result is better than if all the co-occurrences happen in the same region.

According to some example embodiments, a system implements a probabilistic model approach, which can enable the system to avoid picking up moving entities that zigzag in random directions in a same small region. Generally, the expectation is for moving entities to travel in similar directions, at similar speeds, and at a pace that's typical to their associated moving entity type (e.g., a vehicle on a ship should travel like a normal ship). For some example embodiments, the system uses a probabilistic model that captures the likelihood of observations about a sub-voyage, such as relative directions and speeds, given that the moving entities are co-traveling. Using methodologies described in Keogh et al. (1998), A Probabilistic Approach to Fast Pattern Matching in Time Series Databases, and Phillips et al. (2005), Maximum Entropy Modeling of Species Geographic Distributions, the system can combine the observations about a sub-voyage with an exponential model expressed by Equation 2 as follows:

$$P ( {p}_{s} , {p}_{s + 1} , … {,}_{s + L - 1} \vert cotravel ) = \frac{1}{z} exp ( {\sum }_{i} {λ}_{i} {f}_{i} ( {p}_{s} , {p}_{s + 1} , … , {p}_{s + L - 1} ) )$$

In Equation 2, each feature fᵢ is a weighted average of log likelihoods of a particular type of observations across all movements of a sub-voyage, which can be expressed by Equation 3 as follows:

$${f}_{i} ( {p}_{s} , {p}_{s + 1} , … , {p}_{s + L - 1} ) = \frac{1}{{t}_{s + L - 1} - {t}_{s}} {\sum }_{j = s}^{s + L - 2} ( {t}_{j + 1} - {t}_{j} ) log {P}_{i} ( {p}_{j} , {p}_{j + 1} \vert cotravel )$$

In Equation 3, the features are: the squared error between the blue and red positions; the cosine distance between the blue and red lines; the difference between the blue and red speeds; and the speed of the blue moving entity. Each Pᵢ can follow a Gaussian distribution. For example, for modeling the ideal distribution of the squared error between the blue and red positions, the system can use a Gaussian distribution with the mean μ=0. The weighting factor (tⱼ₊₁−tⱼ) models the intuition that movements over long time intervals should carry more weight than tiny movements that are often caused by noise.

Under a probabilistic model approach, a system can use the scoring function expressed by Equation 4 to score trajectories.

$$score ( V ) = {max}_{s} P ( {p}_{s} , {p}_{s + 1} , … , {p}_{s + L - 1} \vert cotravel )$$

For some example embodiments, a larger value of L=20 is effective with the probabilistic model, and allows a system to find longer co-travels. If there's only one feature (e.g., say the squared error), and L=2, then the probabilistic model can be reduced to a Gaussian distribution for the given feature. For estimating the feature probability distributions Pᵢ in Equation 4, the system can extract the features from an unlabeled training set comprising a sample of queries (e.g., selected or targeted moving entities of interest) and the trajectories of other moving entities near them. For various example embodiments, the distribution of the observed feature values is bimodal, where one of the peaks can be presumed to be caused by co-traveling moving entities so Pᵢ can be fit accordingly. In alternative example embodiments, the system fits Pᵢ to X % of the observations closer to the ideal value for co-traveling (the determination of X can be a subjective call).

According to some example embodiments, a system implements a sequence model approach, which can enable a system to determine (e.g., identify or capture) longer co-travels of moving entities by capturing discontiguous co-travels (thereby avoiding the assumption that co-travels of moving entities are contiguous). In this way, the system can identify co-traveling moving entities that spend some time co-traveling (e.g., a vehicle that gets on a ferry only to do a return trip a few days later). This can enable the system to identify co-traveling moving entities covered by different positioning methods that cause significant divergence in their trajectories (e.g., a vehicle on a cargo plane does not emit positional signals between hops, while the cargo plane is covered by satellites throughout the trip).

To determine (e.g., identify or capture) discontiguous co-travels of moving entities, the system of various example embodiments use a hidden semi-Markov model (HSMM) in which observations are dependent on hidden states s∈{co-travel, co-travel}, where each hidden state can correspond to a movement in a voyage. The underlying process is a semi-Markov where state transitions do not occur at all points in time, but only between variable-time movements (e.g., as described in Yu (2010), Hidden Semi-Markov Models). An example of this semi-Markov process is expressed by Equation 5 as follows:

$$P ( S , V ) = {P ( {s}_{1} )}^{{dt}_{1}} {\prod }_{j = 2}^{n - 1} {P ( {s}_{j} \vert {s}_{j - 1} )}^{{dt}_{j}} \cdot {\prod }_{j = 1}^{n - 1} {P ( {p}_{j} , {p}_{j + 1} \vert {s}_{j} )}^{{dt}_{j}}$$

In Equation 5, the weighting factor dtⱼ=tⱼ₊₁−tⱼ can denote the duration of a movement. As the number of movements in a journey approaches infinite, and the duration of each movement approaches 0, the formulation is equivalent to a voyage being chopped up into an infinite number of very small but equal-time movements. The emission probability P(pⱼ, Pⱼ₊₁|sⱼ) can be defined as an exponential model similar expressed by Equation 6 as follows:

$$P ( {p}_{j} , {p}_{j + 1} \vert {s}_{j} ) = \frac{1}{z} exp ( {\sum }_{i} {λ}_{i} log {P}_{i} ( {p}_{j} , {p}_{j + 1} \vert {s}_{j} ) )$$

The estimation of the feature probability distributions Pᵢ follows the same procedure as above, except that we must also estimate a complementary set of distributions Pᵢ(pⱼ, pⱼ₊₁|co-travel) for entities that are not co-traveling. The rest of the model parameters can be set as follows: use a uniform distribution for the initial probability P(s₁); and a highly skewed distribution [[0.99, 0.01]; [0.01, 0.99]] for a transition probability P(sⱼ|sⱼ₋₁) to discourage spurious state transitions.

Since the voyages V can be of various lengths, neither P(S, V) nor the marginal probability P(V) can be useful as a scoring function for determining (e.g., identifying or capturing) discontiguous co-travels of moving entities. Accordingly, the system of some example embodiments choose the best trajectories for a given query (e.g., selected or targeted moving entity of interest), by using a log-odds ratio that is the logarithm of the probability of the most likely state sequence for a voyage (e.g., the Viterbi sequence), divided by the probability of the voyage being not co-travel. An example of this scoring function is expressed by Equation 7 as follows:

$$score ( V ) = log ( {max}_{s} P ( S , V ) / P ( ¬ cotravel , V ) ) = log {max}_{s} P ( S , V ) - log P ( ¬ cotravel , V ) = {max}_{s} ( d {t}_{1} log P ( {s}_{1} ) + {\sum }_{j = 2}^{n - 1} d {t}_{j} log P ( {s}_{j} \vert {s}_{j - 1} ) + {\sum }_{j = 1}^{n - 1} d {t}_{j} log P ( {p}_{j} , {p}_{j + 1} \vert {s}_{j} ) ) - {dt}_{1} log P ( {s}_{1} = ¬ cotravel ) - {\sum }_{j = 2}^{n - 1} d {t}_{j} log P ( {s}_{j} = ¬ cotravel \vert {s}_{j - 1} = ¬ cotravel ) - {\sum }_{j = 1}^{n - 1} d {t}_{j} log P ( {p}_{j} , {p}_{j + 1} \vert {s}_{j} = ¬ cotravel )$$

This scoring function can naturally favor long sequences of co-travel, as the positive and negative terms can largely cancel each other out if the most likely states are co-travel.

According to various example embodiments, a system uses a post-filter to improve the quality of determining (e.g., identifying) co-traveling moving entities by filtering the large number of potential co-traveling trajectories identified (e.g., by a non-probabilistic model approach, a probabilistic model approach, or a sequence model approach). In this way, the post-filter can be used to decide what to show to users. For some example embodiments, a post-filter is applied based on statistics derived from full trajectories, including without limitation: the rank of the trajectories; the distance traveled; the time spent co-traveling; and the score normalized by co-travel time.

To determine the parameters of the post-filter, the system can run the co-travel model over a small training set (e.g., the same training set for determining the parameters of the feature probability distributions Pᵢ), and then labeling the top number (e.g., 10) predictions per query (e.g., per a selected or targeted moving entity of interest) based on the rating scheme provided in Table 1.

TABLE 1

| Plausibility | |
|---|---|
| rating | Meaning |
| 1 | Impossible: the entities were in different regions |
| 2 | Bad, but the entities were in the same region |
| 3 | Borderline |
| 4 | Good: Likely co-travelers that warrant further |
| | investigation |
| 5 | Excellent: No way the entities aren't co-travelers |

For some example embodiments, a grid search is performed to maximize the average plausibility of the training set while maintaining a certain level of recall.

According to some example embodiments, a system improves the speed of co-traveling moving entity analysis using dynamic programming techniques, such as those described by Gong et al. (2020), High-performance Spatiotemporal Trajectory Matching Across Heterogeneous Data Sources. Additionally, to implement co-traveling moving entity analysis in real-time (or near real-time), a system can implement an incremental version of co-travel, in which a mutable accumulated state could be the lattice structure used by a Viterbi decoder for HSMM.

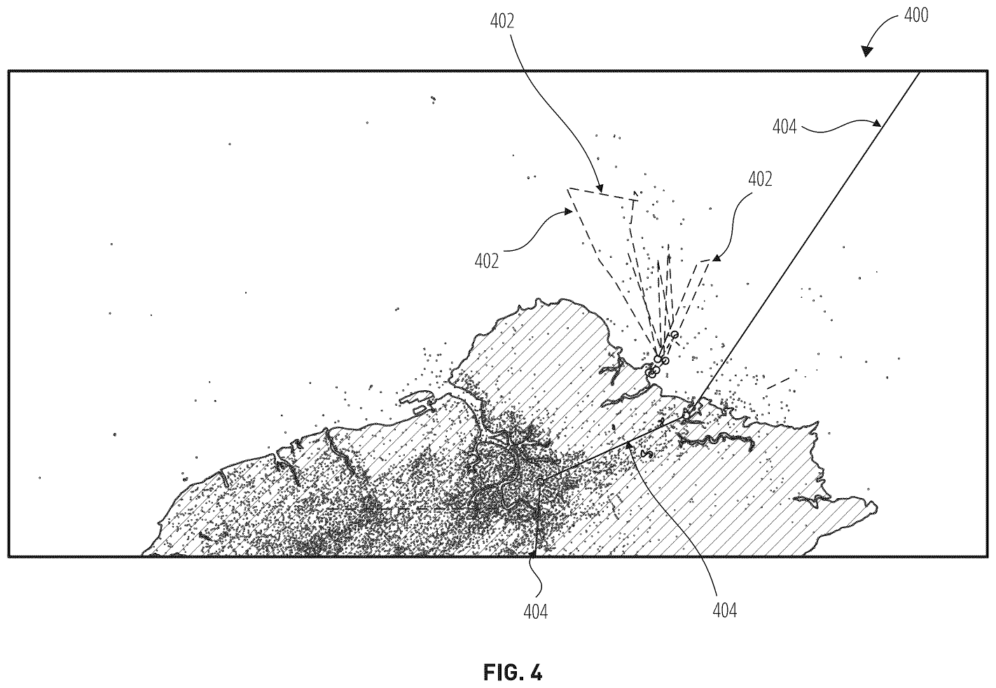

FIG. 3, FIG. 4, and FIG. 5 illustrate examples of analyzing co-traveling moving entities using different models, according to various embodiments of the present disclosure.

As used herein, a query moving entity (or a query) can refer to a selected or targeted moving entity of interest that serves as the basis for a system of some example embodiments to determine (e.g., identify) one or more potential co-traveling moving entities.

Various example embodiments of geospatial analysis of co-traveling moving entities described herein seek to provide technical solutions to a number of technical problems. For instance, conventional trajectory prediction methods can rely on simple extrapolation techniques that fail to account for complex patterns of movement or interactions with other static or moving entities. In comparison, some example embodiments implement multiple sophisticated modeling approaches including a non-probabilistic model that searches for and scores trajectories using weighted scoring functions, a probabilistic model that captures likelihood observations about relative directions and speeds, and a hidden semi-Markov model (HSMM) for identifying discontiguous co-travels. Conventional systems can struggle with managing the connectedness of moving entity information and relationships between entities. Some example embodiments address this through a comprehensive architecture comprising data input components that preprocess trajectory data, trajectory search components that implement algorithms using adjustable fixed radius parameters, and sophisticated scoring mechanisms. Some example embodiments also solve the challenge of identifying complex co-travel patterns where entities may separate and rejoin by implementing a sequence model approach using HSMM with hidden states, feature probability distributions, and post-filtering capabilities based on multiple statistics. To overcome real-time processing performance challenges with large volumes of trajectory data, some example embodiments implement dynamic programming techniques and an incremental version of co-travel analysis that maintains a mutable accumulated state using the lattice structure of a Viterbi decoder for HSMM. Furthermore, to address quality control challenges in co-travel detection that can result in false positives, various example embodiments implement a sophisticated post-filter component with a plausibility rating scheme and grid search optimization to maximize average plausibility while maintaining recall levels.

Reference will now be made in detail to various embodiments of the present disclosure, examples of which are illustrated in the appended drawings. The present disclosure may, however, be embodied in many different forms and should not be construed as being limited to the examples set forth herein.

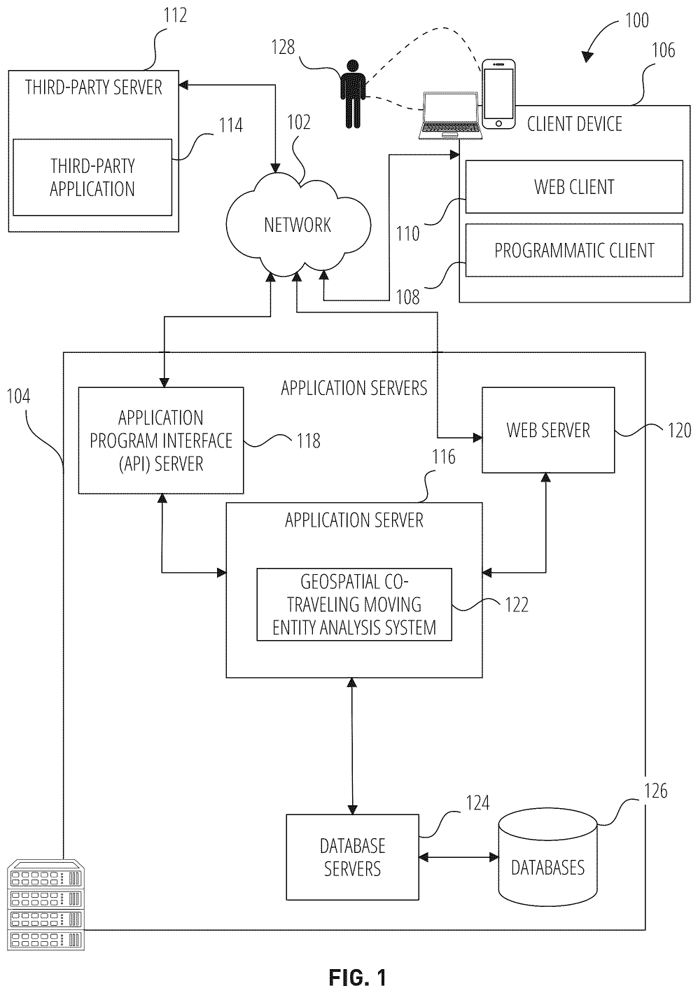

FIG. 1 is a diagrammatic representation of a networked computing environment 100 in which some examples of the present disclosure may be implemented or deployed.

One or more application servers 104 provide server-side functionality via a network 102 to a networked user device, in the form of a client device 106 that is accessed by a user 128. A web client 110 (e.g., a browser) and a programmatic client 108 (e.g., an “app”) are hosted and executed on the web client 110. While certain functions are described herein as being performed by a geospatial co-traveling moving entity analysis system 122 on the application servers 104, it will be appreciated that the location of certain functionality within the application servers 104 is a design choice. For example, it may be technically preferable to initially deploy certain technology and functionality within the application servers 104, but to later migrate this technology and functionality to the programmatic client 108 where the client device 106 performs methodologies described herein.

An Application Program Interface (API) server 118 and a web server 120 provide respective programmatic and web interfaces to application servers 104. A specific application server 116 hosts the geospatial co-traveling moving entity analysis system 122 in accordance with various example embodiments described herein, which includes components, modules and/or applications.

The web client 110 communicates with the geospatial co-traveling moving entity analysis system 122 via the web interface supported by the web server 120. Similarly, the programmatic client 108 communicates with the geospatial co-traveling moving entity analysis system 122 via the programmatic interface provided by the Application Program Interface (API) server 118.

The application server 116 is communicatively coupled to database servers 124, facilitating access to an information storage repository or databases 126. In some examples, the databases 126 includes storage devices that store information to be published and/or processed by the geospatial co-traveling moving entity analysis system 122.

Additionally, a third-party application 114 executing on a third-party server 112, has programmatic access to the application server 116 via the programmatic interface provided by the Application Program Interface (API) server 118. For example, the third-party application 114, using information retrieved from the application server 116, may support one or more features or functions on a website hosted by a third party.

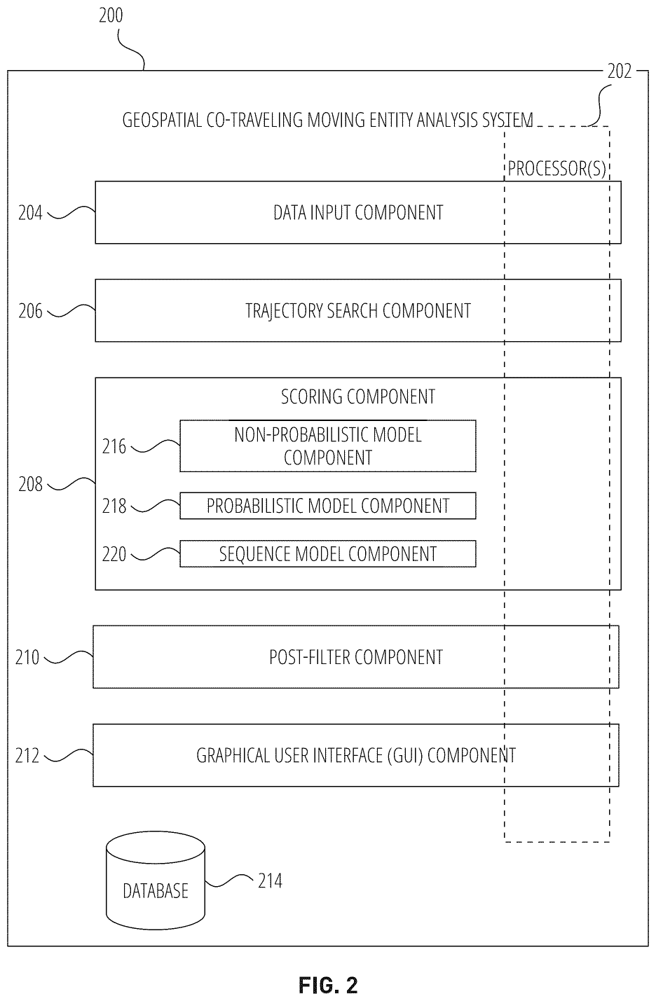

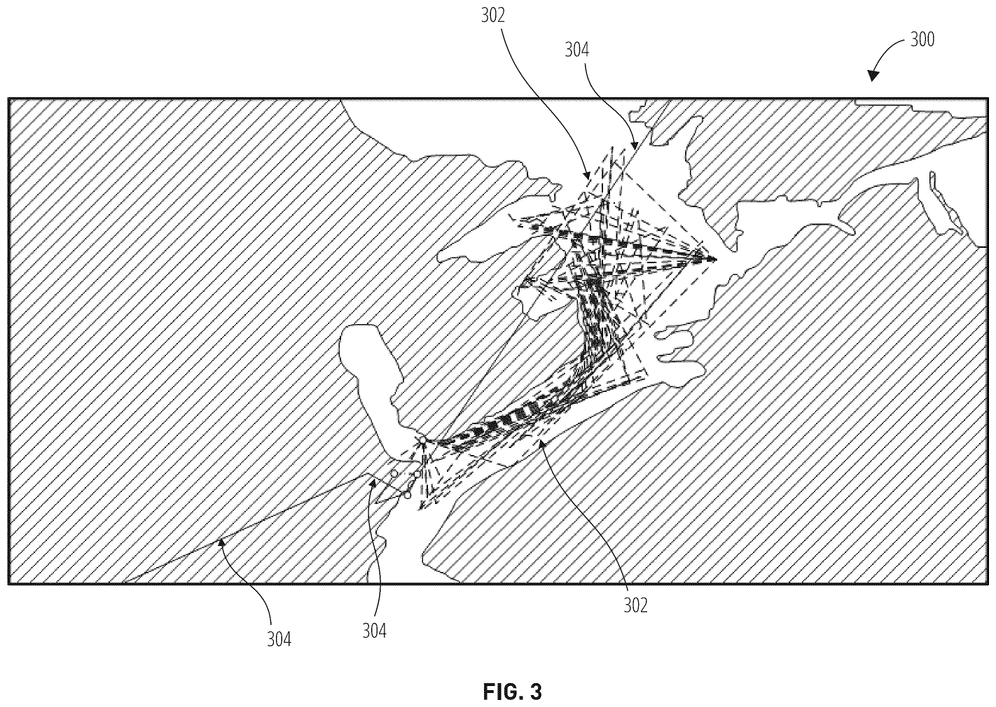

FIG. 2 is a block diagram illustrating an example implementation of a geospatial co-traveling moving entity analysis system 200, according to various embodiments of the present disclosure. For some embodiments, the geospatial co-traveling moving entity analysis system 200 represents an example of the geospatial co-traveling moving entity analysis system 122 described with respect to FIG. 1. As shown, the geospatial co-traveling moving entity analysis system 200 comprises a data input component 204, a trajectory search component 206, a scoring component 208, a post-filter component 210, and a graphical user interface (GUI) component 212. According to various embodiments, one or more of the data input component 204, the trajectory search component 206, the scoring component 208, the post-filter component 210, and the GUI component 212 are implemented by one or more processors 202. Data generated by, or used by, one or more of the data input component 204, the trajectory search component 206, the scoring component 208, and the GUI component 212 is stored on a database (or datastore) 214 of the geospatial co-traveling moving entity analysis system 200.

The data input component 204 can be configured to receive trajectory data from various sources, such as ship positioning systems and transponder locations. This data input component 204 can preprocess the data to ensure consistency and handle any formatting issues.

The trajectory search component 206 can implement an algorithm to search for trajectories that are near a query moving entity's trajectory. The query can refer to a specific entity (e.g., such as a ship) that serves as the basis for determining one or more potential co-traveling moving entities. A query input field (e.g., accessible via a graphical user interface provided by GUI component 212) can allow a user to enter the identifier of the specific entity the user wishes to use as the basis for co-travel moving entity detection. The trajectory search component 206 can use a fixed radius (r) to determine proximity, which can be adjustable based on the moving entity type (e.g., 10 km for ships). The geospatial co-traveling moving entity analysis system 200 compares the query moving entity's trajectory against other moving entities' trajectories to detect potential co-traveling patterns using feature extraction and scoring component 208.

The scoring component 208 can apply a scoring function to score trajectories, which permits the geospatial co-traveling moving entity analysis system 200 to determine (e.g., identify) and prioritize the most likely instances of moving entities co-traveling with the query moving entity. Generally, the scoring function can reward co-occurrences of moving entities over multiple observations (e.g., sightings), and can consider factors such as relative directions and speeds. The implementation of a scoring function can depend on a selected model. As shown, the scoring component 208 can comprise a non-probabilistic model component 216, a probabilistic model component 218, and a sequence model component 220. For example, the non-probabilistic model component 216 can implement a non-probabilistic model approach described herein to scoring trajectories, the probabilistic model component 218 can implement a probabilistic model approach described herein to scoring trajectories, and the sequence model component 220 can implement a sequence model approach (e.g., using a HSMM) described herein to scoring trajectories.

The post-filter component 210 can filter trajectories determined (e.g., identified) based on the scoring component 208. The filtering can be based on statistics derived from full trajectories, such as trajectory ranking, distance traveled, time spent co-traveling, and normalized scores. The post-filter component 210 can help to improve the overall quality of the results.

Results generated by the geospatial co-traveling moving entity analysis system 200 can be accessed or displayed via a graphical user interface provided by the GUI component 212.

FIG. 3, FIG. 4, and FIG. 5 illustrate examples of analyzing co-traveling moving entities using different models, according to various embodiments of the present disclosure.

Referring now to FIG. 3, image 300 illustrates an example of using a non-probabilistic model to determine ships co-traveling with a mobile handset (having a trajectory represented by solid lines 304). As shown in image 300, the best ship trajectory found (represented by dashed lines 302) is one within a very short distance from the handset for a very short period of time (e.g., 8 minutes for 4 movements), but overall the trajectory of the identified ship trajectory bears very little resemblance to the query ship's trajectory.

Referring now to FIG. 4, image 400 illustrates an example of using a probabilistic model to determine ships co-traveling with a query ship (having a trajectory represented by solid lines 404). As shown in image 400, the best ship trajectory (represented by dashed lines 402) is found faster and the ship is shown to be traveling in a similar direction as the query ship for a longer period of time (e.g., 1.5 days for 20 movements).

Referring now to FIG. 5, image 500 illustrates an example of using a HSMM, to determine ships co-traveling with a query ship (having a trajectory represented by solid line 504). In image 500, the ship is island hopping for about 4 days, while the actual time spent co-traveling with the query ship is about 1.3 days. As shown in image 400, the best ship trajectory (represented by dashed lines 502) is found to be co-traveling with the query ship multiple times (e.g., 40 times).

The following Table 2 illustrates example statistics for running a sequence model for co-traveling involving ships, where the feature probability distributions Pᵢ for ships versus ships is fit using a random 0.1% sample of the moving entities, and where the post-filter is fit with plausibility ratings that are labeled on 100s of training examples.

TABLE 2

| Co-Traveling | |
|---|---|
| Type | Statistical Result |
| Ships vs Ships | Total queries: 365,399 |
| | Total queries with co-travelers: 40,723 (11.14%) |
| | Average co-travelers per query: 3.42 |
| | Average co-travel time: 10.43 days |
| | Average end-to-end time: 19.14 days |
| | Average plausibility (based on a small training set): |
| | 3.5 out of 5 |

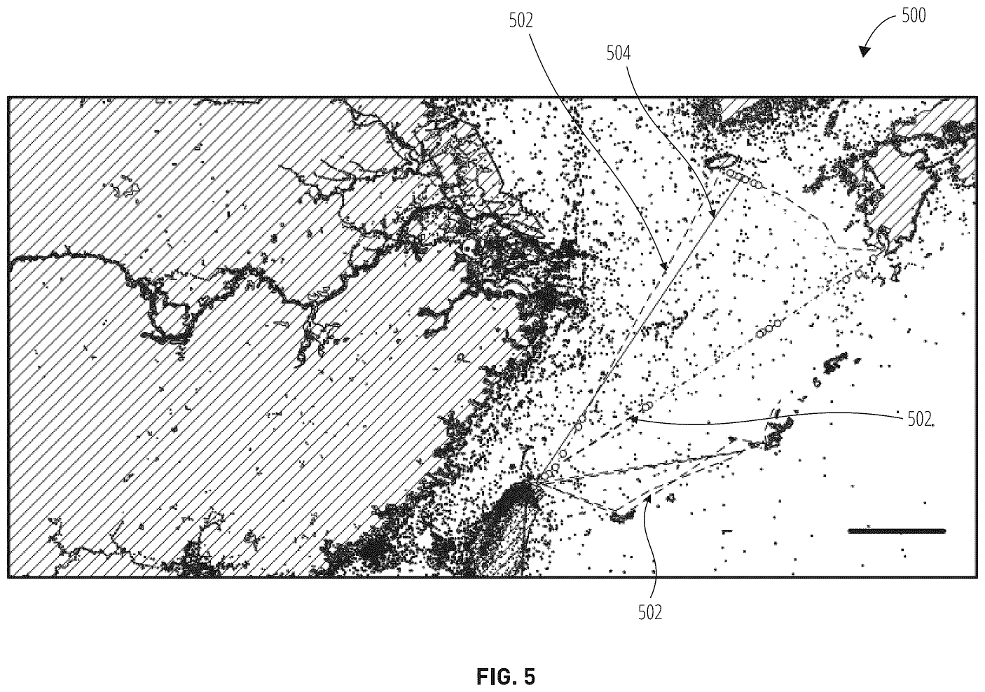

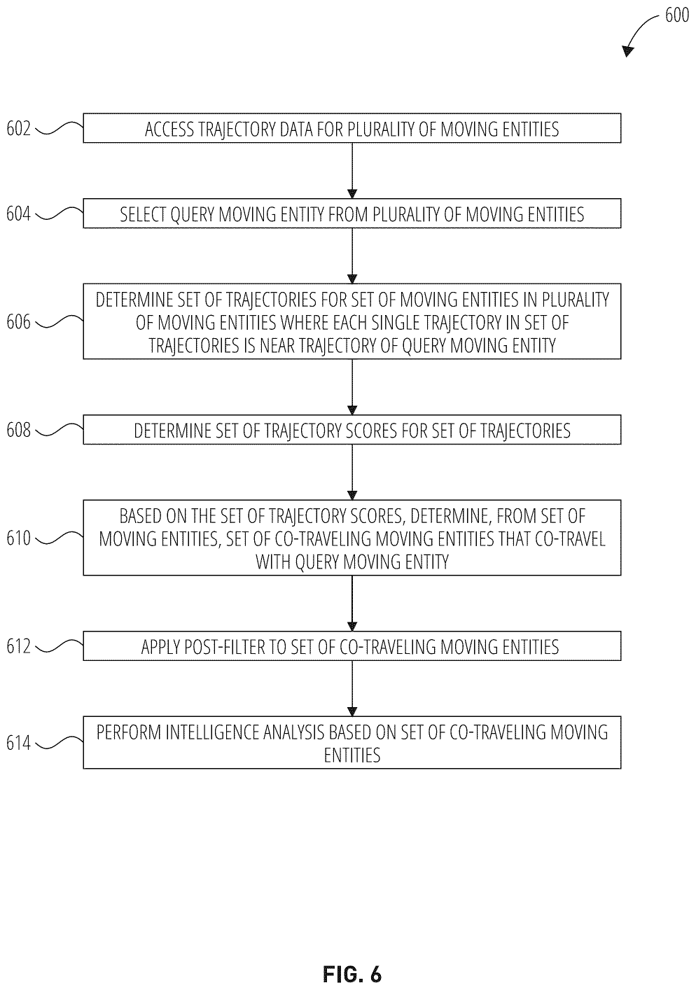

FIG. 6 is a flowchart illustrating an example method 600 for geospatial analysis of co-traveling moving entities (or co-traveling moving objects) using one or more models, according to various example embodiments of the present disclosure. It will be understood that example methods described herein can be performed by a device, such as a computing device executing instructions of a geospatial co-traveling moving entity analysis system (e.g., 122 or 200), in accordance with some example embodiments. Additionally, example methods described herein can be implemented in the form of executable instructions stored on a computer-readable medium or in the form of electronic circuitry. For instance, the operations of method 600 can be represented by executable instructions that, when executed by a processor of a computing device, cause the computing device to perform the method. Depending on the example embodiment, an operation of an example method described herein can be repeated in different ways or involve intervening operations not shown. Though the operations of example methods may be depicted and described in a certain order, the order in which the operations are performed may vary among embodiments, including performing certain operations in parallel. An operation of any of method 600 (or another method described herein) may be performed by a hardware processor (e.g., central processing unit or graphics processing unit) of a computing device (e.g., desktop, server, etc.).

At operation 602, a hardware processor accesses trajectory data for a plurality of moving entities. Depending on the example embodiment, the query moving entity comprises one of a ship, an automotive vehicle, or an aircraft. For some example embodiments, the trajectory data comprises a time-ordered sequence of coordinates (e.g., lat and long coordinates) for a given moving entity, which can take the format of: time1, lat1, long1; time2, lat2, long2; etc., During operation 604, the hardware processor selects a query moving entity from the plurality of moving entities. Depending on the example embodiment, the query moving entity can represent a moving entity of interest for analysis (e.g., intelligence analysis) by a user. For some example embodiments, the moving entity of interest is selected automatically by using co-traveling patterns to derive entity relationships in an automatically-constructed knowledge graph.

For operation 606, the hardware processor determines a set of trajectories for a set of moving entities in the plurality of moving entities where each single trajectory in the set of trajectories is near a trajectory of the query moving entity. For some example embodiments, a select trajectory of a select moving entity in the set of moving entities is determined to be near the query moving entity in response to at least one movement of the select trajectory being within a fixed radius from the query moving entity at a given time instance. The fixed radius can be adjustable based on a moving entity type of the query moving entity. For instance, the fixed radius can be set to 10 km when the query moving entity comprises a ship.

At operation 608, the hardware processor determines (e.g., searches for) a set of trajectory scores for the set of trajectories. Trajectory score values can vary between different example embodiments. For instance, the range of trajectory score values can be based on a log-odd ratio, and can be a positive or a negative value. For various example embodiments, operation 608 comprises scoring each individual trajectory in the set of trajectories using a scoring function that evaluates, over multiple observations, co-occurrence of the query moving entity with an individual moving entity associated with the individual trajectory. For some example embodiments, scoring the individual trajectory using the scoring function comprises using a non-probabilistic model that calculates a minimum weighted sum squared errors between positions of the query moving entity and the individual moving entity associated with the individual trajectory. Depending on the example embodiment, the non-probabilistic model used can be configured to apply a weighting factor based on a distance traveled by either the query moving entity or the individual moving entity during a sub-voyage, where the sub-voyage comprises a time-consecutive subsequence of proximities in a voyage (e.g., of both the query moving entity and the individual moving entity). For various example embodiments, scoring the individual trajectory using the scoring function comprises using a probabilistic model that captures a likelihood of observations about relative directions and speeds of moving entities. For example, the probabilistic model used can be configured to combine observations using an exponential model with one or more features. Depending on the example embodiment, the one or more features can comprise at least one of squared error between positions of moving entities, cosine distance between movement lines of moving entities, difference between speeds of moving entities, or speed of moving entities. Additionally, at least one feature (of the one or more features of the exponential model) can follow a Gaussian distribution. As another example, the probabilistic model use can be configured to apply a weighting factor that assigns more weight to movements over long time intervals compared to movements over short time intervals. For some example embodiments, scoring the individual trajectory using the scoring function comprises using a hidden semi-Markov model to identify discontiguous co-travels between the query moving entity and the individual moving entity associated with the individual trajectory. For instance, the hidden semi-Markov model can use a scoring function based on a log-odds ratio of a probability of a most likely state sequence divided by a probability of non-co-travel.

For operation 610, the hardware processor determines, from the set of moving entities, a set of co-traveling moving entities that co-travel with the query moving entity. According to various example embodiments, the hardware processor determines the set of co-traveling moving entities based on the set of trajectory scores.

For operation 612 (and prior to operation 614), the hardware processor applies a post-filter to the set of co-traveling moving entities based on one or more factors. Depending on the example embodiment, the one or more factors can include, without limitation, rank of trajectories, distance traveled, time spent co-traveling, and score normalized by co-travel time.

At operation 614, the hardware processor performs an intelligence analysis based on the set of co-traveling moving entities. For some example embodiments, the query moving entity comprises a rogue ship (e.g., on a covert or non-covert military mission), and the intelligence analysis comprises identifying one or more other moving entities co-traveling with the rogue ship. A use case can be automatic knowledge graph construction, where the co-traveling algorithm is used to perform spatiotemporal joins between data sources with disjoint primary keys. Another example use case can be drug enforcement, where the co-traveling algorithm is used to identify motherships that drop off illegal drugs to smaller vessels along the coast.

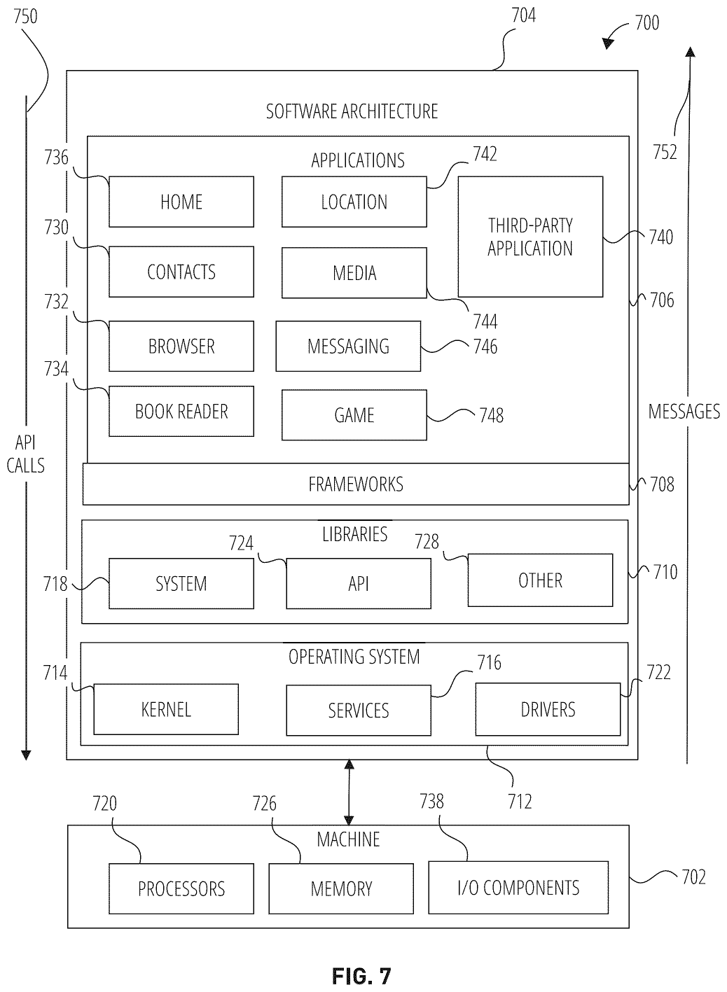

FIG. 7 is a block diagram 700 illustrating a software architecture 704, which can be installed on any one or more of the devices described herein. The software architecture 704 is supported by hardware such as a machine 702 that includes processors 720, memory 726, and I/O components 738. In this example, the software architecture 704 can be conceptualized as a stack of layers, where each layer provides a particular functionality. The software architecture 704 includes layers such as an operating system 712, libraries 710, frameworks 708, and applications 706. Operationally, the applications 706 invoke API calls 750 through the software stack and receive messages 752 in response to the API calls 750.

The operating system 712 manages hardware resources and provides common services. The operating system 712 includes, for example, a kernel 714, services 716, and drivers 722. The kernel 714 acts as an abstraction layer between the hardware and the other software layers. For example, the kernel 714 provides memory management, Processor management (e.g., scheduling), component management, networking, and security settings, among other functionalities. The services 716 can provide other common services for the other software layers. The drivers 722 are responsible for controlling or interfacing with the underlying hardware. For instance, the drivers 722 can include display drivers, camera drivers, BLUETOOTH® or BLUETOOTH® Low Energy drivers, flash memory drivers, serial communication drivers (e.g., Universal Serial Bus (USB) drivers), WI-FI® drivers, audio drivers, and power management drivers.

The libraries 710 provide a low-level common infrastructure used by the applications 706. The libraries 710 can include system libraries 718 (e.g., C standard library) that provide functions such as memory allocation functions, string manipulation functions, mathematic functions, and the like. In addition, the libraries 710 can include API libraries 724 such as media libraries (e.g., libraries to support presentation and manipulation of various media formats such as Moving Picture Experts Group-4 (MPEG4), Advanced Video Coding (H.264 or AVC), Moving Picture Experts Group Layer-3 (MP3), Advanced Audio Coding (AAC), Adaptive Multi-Rate (AMR) audio codec, Joint Photographic Experts Group (JPEG or JPG), or Portable Network Graphics (PNG)), graphics libraries (e.g., an OpenGL framework used to render in two dimensions (2D) and three dimensions (3D) in a graphic content on a display), database libraries (e.g., SQLite to provide various relational database functions), web libraries (e.g., Web Kit to provide web browsing functionality), and the like. The libraries 710 can also include a wide variety of other libraries 728 to provide many other APIs to the applications 706.

The frameworks 708 provide a high-level common infrastructure used by the applications 706. For example, the frameworks 708 provide various graphical user interface (GUI) functions, high-level resource management, and high-level location services. The frameworks 708 can provide a broad spectrum of other APIs that can be used by the applications 706, some of which may be specific to a particular operating system or platform.

In some examples, the applications 706 may include a home application 736, a contacts application 730, a browser application 732, a book reader application 734, a location application 742, a media application 744, a messaging application 746, a game application 748, and a broad assortment of other applications such as a third-party application 740. The applications 706 are programs that execute functions defined in the programs. Various programming languages can be employed to create one or more of the applications 706, structured in a variety of manners, such as object-oriented programming languages (e.g., Objective-C, Java, or C++) or procedural programming languages (e.g., C or assembly language). In a specific example, the third-party application 740 (e.g., an application developed using the ANDROID™ or IOS™ software development kit (SDK) by an entity other than the vendor of the particular platform) may be mobile software running on a mobile operating system such as IOS™, ANDROID™, WINDOWS® Phone, or another mobile operating system. In this example, the third-party application 740 can invoke the API calls 750 provided by the operating system 712 to facilitate functionality described herein.

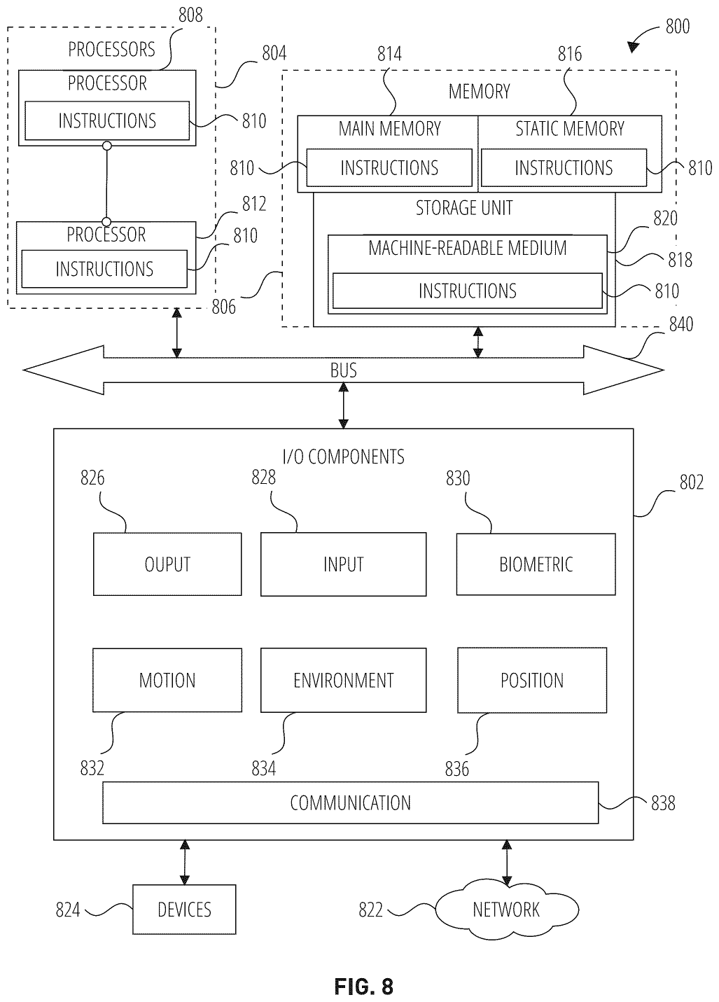

FIG. 8 is a diagrammatic representation of the machine 800 within which instructions 810 (e.g., software, a program, an application, an applet, an app, or other executable code) for causing the machine 800 to perform any one or more of the methodologies discussed herein may be executed. For example, the instructions 810 may cause the machine 800 to execute any one or more of the methods described herein. The instructions 810 transform the general, non-programmed machine 800 into a particular machine 800 programmed to carry out the described and illustrated functions in the manner described. The machine 800 may operate as a standalone device or be coupled (e.g., networked) to other machines. In a networked deployment, the machine 800 may operate in the capacity of a server machine or a client machine in a server-client network environment, or as a peer machine in a peer-to-peer (or distributed) network environment. The machine 800 may comprise, but not be limited to, a server computer, a client computer, a personal computer (PC), a tablet computer, a laptop computer, a netbook, a set-top box (STB), an entertainment media system, a cellular telephone, a smartphone, a mobile device, a wearable device (e.g., a smartwatch), a smart home device (e.g., a smart appliance), other smart devices, a web appliance, a network router, a network switch, a network bridge, or any machine capable of executing the instructions 810, sequentially or otherwise, that specify actions to be taken by the machine 800. Further, while a single machine 800 is illustrated, the term “machine” may include a collection of machines that individually or jointly execute the instructions 810 to perform any one or more of the methodologies discussed herein.

The machine 800 may include processors 804, memory 806, and I/O components 802, which may be configured to communicate via a bus 840. In some examples, the processors 804 (e.g., a Central Processing Unit (CPU), a Reduced Instruction Set Computing (RISC) Processor, a Complex Instruction Set Computing (CISC) Processor, a Graphics Processing Unit (GPU), a Digital Signal Processor (DSP), an Application-Specific Integrated Circuit (ASIC), a Radio-Frequency Integrated Circuit (RFIC), another Processor, or any suitable combination thereof) may include, for example, a Processor 808 and a Processor 812 that execute the instructions 810. The term “Processor” is intended to include multi-core processors that may comprise two or more independent processors (sometimes referred to as “cores”) that may execute instructions contemporaneously. Although FIG. 8 shows multiple processors 804, the machine 800 may include a single processor with a single core, a single processor with multiple cores (e.g., a multi-core processor), multiple processors with a single core, multiple processors with multiples cores, or any combination thereof.

The memory 806 includes a main memory 814, a static memory 816, and a storage unit 818, both accessible to the processors 804 via the bus 840. The main memory 806, the static memory 816, and storage unit 818 store the instructions 810 embodying any one or more of the methodologies or functions described herein. The instructions 810 may also reside, wholly or partially, within the main memory 814, within the static memory 816, within machine-readable medium 820 within the storage unit 818, within the processors 804 (e.g., within the processor's cache memory), or any suitable combination thereof, during execution thereof by the machine 800.

The I/O components 802 may include various components to receive input, provide output, produce output, transmit information, exchange information, or capture measurements. The specific I/O components 802 included in a particular machine depend on the type of machine. For example, portable machines such as mobile phones may include a touch input device or other such input mechanisms, while a headless server machine will likely not include such a touch input device. The I/O components 802 may include many other components not shown in FIG. 8. In various examples, the I/O components 802 may include output components 826 and input components 828. The output components 826 may include visual components (e.g., a display such as a plasma display panel (PDP), a light-emitting diode (LED) display, a liquid crystal display (LCD), a projector, or a cathode ray tube (CRT)), acoustic components (e.g., speakers), haptic components (e.g., a vibratory motor, resistance mechanisms), or other signal generators. The input components 828 may include alphanumeric input components (e.g., a keyboard, a touch screen configured to receive alphanumeric input, a photo-optical keyboard, or other alphanumeric input components), point-based input components (e.g., a mouse, a touchpad, a trackball, a joystick, a motion sensor, or another pointing instrument), tactile input components (e.g., a physical button, a touch screen that provides location and/or force of touches or touch gestures, or other tactile input components), audio input components (e.g., a microphone), and the like.

In further examples, the I/O components 802 may include biometric components 830, motion components 832, environmental components 834, or position components 836, among a wide array of other components. For example, the biometric components 830 include components to detect expressions (e.g., hand expressions, facial expressions, vocal expressions, body gestures, or eye-tracking), measure biosignals (e.g., blood pressure, heart rate, body temperature, perspiration, or brain waves), or identify a person (e.g., voice identification, retinal identification, facial identification, fingerprint identification, or electroencephalogram-based identification). The motion components 832 include acceleration sensor components (e.g., accelerometer), gravitation sensor components, rotation sensor components (e.g., gyroscope). The environmental components 834 include, for example, one or cameras, illumination sensor components (e.g., photometer), temperature sensor components (e.g., one or more thermometers that detect ambient temperature), humidity sensor components, pressure sensor components (e.g., barometer), acoustic sensor components (e.g., one or more microphones that detect background noise), proximity sensor components (e.g., infrared sensors that detect nearby objects), gas sensors (e.g., gas detection sensors to detection concentrations of hazardous gases for safety or to measure pollutants in the atmosphere), or other components that may provide indications, measurements, or signals corresponding to a surrounding physical environment. The position components 836 include location sensor components (e.g., a Global Positioning System (GPS) receiver component), altitude sensor components (e.g., altimeters or barometers that detect air pressure from which altitude may be derived), orientation sensor components (e.g., magnetometers), and the like.

Communication may be implemented using a wide variety of technologies. The I/O components 802 further include communication components 838 operable to couple the machine 800 to a network 822 or devices 824 via respective coupling or connections. For example, the communication components 838 may include a network interface Component or another suitable device to interface with the network 822. In further examples, the communication components 838 may include wired communication components, wireless communication components, cellular communication components, Near Field Communication (NFC) components, Bluetooth® components (e.g., Bluetooth® Low Energy), Wi-Fi® components, and other communication components to provide communication via other modalities. The devices 824 may be another machine or any of a wide variety of peripheral devices (e.g., a peripheral device coupled via a USB).

Moreover, the communication components 838 may detect identifiers or include components operable to detect identifiers. For example, the communication components 838 may include Radio Frequency Identification (RFID) tag reader components, NFC smart tag detection components, optical reader components (e.g., an optical sensor to detect one-dimensional bar codes such as Universal Product Code (UPC) bar code, multi-dimensional bar codes such as Quick Response (QR) code, Aztec code, Data Matrix, Data glyph, Maxi Code, PDF417, Ultra Code, UCC RSS-2D bar code, and other optical codes), or acoustic detection components (e.g., microphones to identify tagged audio signals). In addition, a variety of information may be derived via the communication components 838, such as location via Internet Protocol (IP) geolocation, location via Wi-Fi® signal triangulation, or location via detecting an NFC beacon signal that may indicate a particular location.

The various memories (e.g., main memory 814, static memory 816, and/or memory of the processors 804) and/or storage unit 818 may store one or more sets of instructions and data structures (e.g., software) embodying or used by any one or more of the methodologies or functions described herein. These instructions (e.g., the instructions 810), when executed by processors 804, cause various operations to implement the disclosed examples.

The instructions 810 may be transmitted or received over the network 822, using a transmission medium, via a network interface device (e.g., a network interface component included in the communication components 838) and using any one of several well-known transfer protocols (e.g., hypertext transfer protocol (HTTP)). Similarly, the instructions 810 may be transmitted or received using a transmission medium via a coupling (e.g., a peer-to-peer coupling) to the devices 824.

Described implementations of the subject matter can include one or more features, alone or in combination as illustrated below by way of examples.

Example 1 is a system for analyzing geospatial moving entities, the system comprising: a memory storing instructions; and a hardware processor operatively coupled to the memory, the instructions when executed by the hardware processor causing the hardware processor to perform operations comprising: accessing trajectory data for a plurality of moving entities; selecting a query moving entity from the plurality of moving entities; determining a set of trajectories for a set of moving entities in the plurality of moving entities where each single trajectory in the set of trajectories is near a trajectory of the query moving entity; determining a set of trajectory scores for the set of trajectories, the determining of the set of trajectory scores comprising scoring each individual trajectory in the set of trajectories using a scoring function that evaluates, over multiple observations, co-occurrence of the query moving entity with an individual moving entity associated with the individual trajectory; determining, from the set of moving entities, a set of co-traveling moving entities that co-travel with the query moving entity, the determining of the set of co-traveling moving entities being based on the set of trajectory scores; and performing an intelligence analysis based on the set of co-traveling moving entities.

In Example 2, the subject matter of Example 1 includes, wherein the query moving entity comprises a rogue ship, and wherein the intelligence analysis comprises identifying one or more other moving entities co-traveling with the rogue ship.

In Example 3, the subject matter of Examples 1-2 includes, wherein the determining of the set of trajectories for the set of moving entities comprises: determining that a select trajectory of a select moving entity in the set of moving entities is near the query moving entity in response to at least one movement of the select trajectory being within a fixed radius from the query moving entity at a given time instance.

In Example 4, the subject matter of Example 3 includes, wherein the fixed radius is adjustable based on a moving entity type of the query moving entity.

In Example 5, the subject matter of Example 4 includes, ° when the query moving entity comprises a ship.

In Example 6, the subject matter of Examples 4-5 includes, ° when the query moving entity comprises a transponder.

In Example 7, the subject matter of Examples 1-6 includes, wherein the scoring of the individual trajectory in the set of trajectories using the scoring function comprises: using a non-probabilistic model that calculates a minimum weighted sum squared errors between positions of the query moving entity and the individual moving entity associated with the individual trajectory.

In Example 8, the subject matter of Example 7 includes, wherein the non-probabilistic model is configured to apply a weighting factor based on a distance traveled by either the query moving entity or the individual moving entity during a sub-voyage, sub-voyage comprising a time-consecutive subsequence of proximities in a voyage.

In Example 9, the subject matter of Examples 1-8 includes, wherein the scoring of the individual trajectory in the set of trajectories using the scoring function comprises: using a probabilistic model that captures a likelihood of observations about relative directions and speeds of moving entities.

In Example 10, the subject matter of Example 9 includes, wherein the probabilistic model is configured to combine observations using an exponential model with one or more features, the one or more features comprising at least one of: squared error between positions of moving entities; cosine distance between movement lines of moving entities; difference between speeds of moving entities; or speed of moving entities.

In Example 11, the subject matter of Example 10 includes, wherein at least one feature of the one or more features follows a Gaussian distribution.

In Example 12, the subject matter of Examples 9-11 includes, wherein the probabilistic model is configured to apply a weighting factor that assigns more weight to movements over long time intervals compared to movements over short time intervals.

In Example 13, the subject matter of Examples 1-12 includes, wherein the scoring of the individual trajectory in the set of trajectories using the scoring function comprises: using a hidden semi-Markov model to identify discontiguous co-travels between the query moving entity and the individual moving entity associated with the individual trajectory.

In Example 14, the subject matter of Example 13 includes, wherein the hidden semi-Markov model uses a scoring function based on a log-odds ratio of a probability of a most likely state sequence divided by a probability of non-co-travel.

In Example 15, the subject matter of Examples 1-14 includes, wherein the operations comprise: prior to performing the intelligence analysis based on the set of co-traveling moving entities, applying a post-filter to the set of co-traveling moving entities based on one or more of: rank of trajectories; distance traveled; time spent co-traveling; and score normalized by co-travel time.

In Example 16, the subject matter of Examples 1-15 includes, wherein the query moving entity comprises one of a ship, an automotive vehicle, or an aircraft.

Example 17 is a machine storage medium comprising instructions that, when executed by a hardware processor of a device, cause the device to perform operations that implement any of Examples 1-16.

Example 18 is a method to implement any of Examples 1-16.

### Glossary

“Carrier Signal” refers to any intangible medium capable of storing, encoding, or carrying instructions for execution by the machine, and includes digital or analog communications signals or other intangible media to facilitate communication of such instructions. Instructions may be transmitted or received over a network using a transmission medium via a network interface device.

“Communication Network” refers to one or more portions of a network that may be an ad hoc network, an intranet, an extranet, a virtual private network (VPN), a local area network (LAN), a wireless LAN (WLAN), a wide area network (WAN), a wireless WAN (WWAN), a metropolitan area network (MAN), the Internet, a portion of the Internet, a portion of the Public Switched Telephone Network (PSTN), a plain old telephone service (POTS) network, a cellular telephone network, a wireless network, a Wi-Fi® network, another type of network, or a combination of two or more such networks. For example, a network or a portion of a network may include a wireless or cellular network, and the coupling may be a Code Division Multiple Access (CDMA) connection, a Global System for Mobile communications (GSM) connection, or other types of cellular or wireless coupling. In this example, the coupling may implement any of a variety of types of data transfer technology, such as Single Carrier Radio Transmission Technology (1×RTT), Evolution-Data Optimized (EVDO) technology, General Packet Radio Service (GPRS) technology, Enhanced Data rates for GSM Evolution (EDGE) technology, third Generation Partnership Project (3GPP) including 3G, fourth-generation wireless (4G) networks, Universal Mobile Telecommunications System (UMTS), High-Speed Packet Access (HSPA), Worldwide Interoperability for Microwave Access (WiMAX), Long Term Evolution (LTE) standard, others defined by various standard-setting organizations, other long-range protocols, or other data transfer technology.

“Component” refers to a device, physical entity, or logic having boundaries defined by function or subroutine calls, branch points, APIs, or other technologies that provide for the partitioning or modularization of particular processing or control functions. Components may be combined via their interfaces with other components to carry out a machine process. A component may be a packaged functional hardware unit designed for use with other components and a part of a program that usually performs a particular function of related functions. Components may constitute either software components (e.g., code embodied on a machine-readable medium) or hardware components. A “hardware component” is a tangible unit capable of performing certain operations and may be configured or arranged in a certain physical manner In examples, one or more computer systems (e.g., a standalone computer system, a client computer system, or a server computer system) or one or more hardware components of a computer system (e.g., a processor or a group of processors) may be configured by software (e.g., an application or application portion) as a hardware component that operates to perform certain operations as described herein. A hardware component may also be implemented mechanically, electronically, or any suitable combination thereof. For example, a hardware component may include dedicated circuitry or logic that is permanently configured to perform certain operations. A hardware component may be a special-purpose processor, such as a field-programmable gate array (FPGA) or an application specific integrated circuit (ASIC).A hardware component may also include programmable logic or circuitry that is temporarily configured by software to perform certain operations. For example, a hardware component may include software executed by a general-purpose processor or other programmable processor. Once configured by such software, hardware components become specific machines (or specific components of a machine) uniquely tailored to perform the configured functions and are no longer general-purpose processors. A decision to implement a hardware component mechanically, in dedicated and permanently configured circuitry, or in temporarily configured circuitry (e.g., configured by software), may be driven by cost and time considerations. Accordingly, the phrase “hardware component” (or “hardware-implemented component”) should be understood to encompass a tangible entity, be that an entity that is physically constructed, permanently configured (e.g., hardwired), or temporarily configured (e.g., programmed) to operate in a certain manner or to perform certain operations described herein. Considering examples in which hardware components are temporarily configured (e.g., programmed), each of the hardware components need not be configured or instantiated at any one instance in time. For example, where a hardware component comprises a general-purpose processor configured by software to become a special-purpose processor, the general-purpose processor may be configured as different special-purpose processors (e.g., comprising different hardware components) at different times. Software accordingly configures a particular processor or processors, for example, to constitute a particular hardware component at one instance of time and to constitute a different hardware component at a different instance of time. Hardware components can provide information to, and receive information from, other hardware components. Accordingly, the described hardware components may be regarded as being communicatively coupled. Where multiple hardware components exist contemporancously, communications may be achieved through signal transmission (e.g., over appropriate circuits and buses) between or among two or more of the hardware components. In examples in which multiple hardware components are configured or instantiated at different times, communications between such hardware components may be achieved, for example, through the storage and retrieval of information in memory structures to which the multiple hardware components have access. For example, one hardware component may perform an operation and store the output of that operation in a memory device to which it is communicatively coupled. A further hardware component may then, at a later time, access the memory device to retrieve and process the stored output. Hardware components may also initiate communications with input or output devices, and can operate on a resource (e.g., a collection of information). The various operations of example methods described herein may be performed, at least partially, by one or more processors that are temporarily configured (e.g., by software) or permanently configured to perform the relevant operations. Whether temporarily or permanently configured, such processors may constitute processor-implemented components that operate to perform one or more operations or functions described herein. As used herein, “processor-implemented component” refers to a hardware component implemented using one or more processors. Similarly, the methods described herein may be at least partially processor-implemented, with a particular processor or processors being an example of hardware. For example, at least some of the operations of methods described herein may be performed by one or more processors or processor-implemented components. Moreover, the one or more processors may also operate to support performance of the relevant operations in a “cloud computing” environment or as a “software as a service” (SaaS).For example, at least some of the operations may be performed by a group of computers (as examples of machines including processors), with these operations being accessible via a network (e.g., the Internet) and via one or more appropriate interfaces (e.g., an API). The performance of certain of the operations may be distributed among the processors, not only residing within a single machine, but deployed across a number of machines. In some examples, the processors or processor-implemented components may be located in a single geographic location (e.g., within a home environment, an office environment, or a server farm). In some examples, the processors or processor-implemented components may be distributed across a number of geographic locations.

“Computer-Readable Medium” refers to both machine-storage media and transmission media. Thus, the terms include both storage devices/media and carrier waves/modulated data signals. The terms “machine-readable medium,” “computer-readable medium” and “device-readable medium” mean the same thing and may be used interchangeably in this disclosure.

“Machine-Storage Medium” refers to a single or multiple storage devices and/or media (e.g., a centralized or distributed database, and/or associated caches and servers) that store executable instructions, routines and/or data. The term includes solid-state memories, and optical and magnetic media, including memory internal or external to processors. Specific examples of machine-storage media, computer-storage media and/or device-storage media include non-volatile memory, including by way of example semiconductor memory devices, e.g., erasable programmable read-only memory (EPROM), electrically erasable programmable read-only memory (EEPROM), FPGA, and flash memory devices; magnetic disks such as internal hard disks and removable disks; magneto-optical disks; and CD-ROM and DVD-ROM disks The terms “machine-storage medium”, “device-storage medium,” “computer-storage medium” mean the same thing and may be used interchangeably in this disclosure. The terms “machine-storage media,” “computer-storage media,” and “device-storage media” specifically exclude carrier waves, modulated data signals, and other such media, at least some of which are covered under the term “signal medium.”

“Module” refers to logic having boundaries defined by function or subroutine calls, branch points, Application Program Interfaces (APIs), or other technologies that provide for the partitioning or modularization of particular processing or control functions. Modules are typically combined via their interfaces with other modules to carry out a machine process. A module may be a packaged functional hardware unit designed for use with other components and a part of a program that usually performs a particular function of related functions. Modules may constitute either software modules (e.g., code embodied on a machine-readable medium) or hardware modules. A “hardware module” is a tangible unit capable of performing certain operations and may be configured or arranged in a certain physical manner. In various example embodiments, one or more computer systems (e.g., a standalone computer system, a client computer system, or a server computer system) or one or more hardware modules of a computer system (e.g., a processor or a group of processors) may be configured by software (e.g., an application or application portion) as a hardware module that operates to perform certain operations as described herein. In some embodiments, a hardware module may be implemented mechanically, electronically, or any suitable combination thereof. For example, a hardware module may include dedicated circuitry or logic that is permanently configured to perform certain operations. For example, a hardware module may be a special-purpose processor, such as a Field-Programmable Gate Array (FPGA) or an Application Specific Integrated Circuit (ASIC). A hardware module may also include programmable logic or circuitry that is temporarily configured by software to perform certain operations. For example, a hardware module may include software executed by a general-purpose processor or other programmable processor. Once configured by such software, hardware modules become specific machines (or specific components of a machine) uniquely tailored to perform the configured functions and are no longer general-purpose processors. It will be appreciated that the decision to implement a hardware module mechanically, in dedicated and permanently configured circuitry, or in temporarily configured circuitry (e.g., configured by software) may be driven by cost and time considerations. Accordingly, the phrase “hardware module” (or “hardware-implemented module”) should be understood to encompass a tangible entity, be that an entity that is physically constructed, permanently configured (e.g., hardwired), or temporarily configured (e.g., programmed) to operate in a certain manner or to perform certain operations described herein. Considering embodiments in which hardware modules are temporarily configured (e.g., programmed), each of the hardware modules need not be configured or instantiated at any one instance in time. For example, where a hardware module comprises a general-purpose processor configured by software to become a special-purpose processor, the general-purpose processor may be configured as respectively different special-purpose processors (e.g., comprising different hardware modules) at different times. Software accordingly configures a particular processor or processors, for example, to constitute a particular hardware module at one instance of time and to constitute a different hardware module at a different instance of time. Hardware modules can provide information to, and receive information from, other hardware modules. Accordingly, the described hardware modules may be regarded as being communicatively coupled. Where multiple hardware modules exist contemporaneously, communications may be achieved through signal transmission (e.g., over appropriate circuits and buses) between or among two or more of the hardware modules. In embodiments in which multiple hardware modules are configured or instantiated at different times, communications between such hardware modules may be achieved, for example, through the storage and retrieval of information in memory structures to which the multiple hardware modules have access. For example, one hardware module may perform an operation and store the output of that operation in a memory device to which it is communicatively coupled. A further hardware module may then, at a later time, access the memory device to retrieve and process the stored output. Hardware modules may also initiate communications with input or output devices, and can operate on a resource (e.g., a collection of information). The various operations of example methods and routines described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions described herein. As used herein, “processor-implemented module” refers to a hardware module implemented using one or more processors. Similarly, the methods described herein may be at least partially processor-implemented, with a particular processor or processors being an example of hardware. For example, at least some of the operations of a method may be performed by one or more processors or processor-implemented modules. Moreover, the one or more processors may also operate to support performance of the relevant operations in a “cloud computing” environment or as a “software as a service” (SaaS). For example, at least some of the operations may be performed by a group of computers (as examples of machines including processors), with these operations being accessible via a network (e.g., the Internet) and via one or more appropriate interfaces (e.g., an Application Program Interface (API)). The performance of certain of the operations may be distributed among the processors, not only residing within a single machine, but deployed across a number of machines. In some example embodiments, the processors or processor-implemented modules may be located in a single geographic location (e.g., within a home environment, an office environment, or a server farm). In other example embodiments, the processors or processor-implemented modules may be distributed across a number of geographic locations.

“Processor” refers to any circuit or virtual circuit (a physical circuit emulated by logic executing on an actual processor) that manipulates data values according to control signals (e.g., “commands”, “op codes”, “machine code”, etc.) and which produces corresponding output signals that are applied to operate a machine. A processor may, for example, be a Central Processing Unit (CPU), a Reduced Instruction Set Computing (RISC) Processor, a Complex Instruction Set Computing (CISC) Processor, a Graphics Processing Unit (GPU), a Digital Signal Processor (DSP), an Application Specific Integrated Circuit (ASIC), a Radio-Frequency Integrated Circuit (RFIC) or any combination thereof. A processor may further be a multi-core processor having two or more independent processors (sometimes referred to as “cores”) that may execute instructions contemporaneously.

“Signal Medium” refers to any intangible medium that is capable of storing, encoding, or carrying the instructions for execution by a machine and includes digital or analog communications signals or other intangible media to facilitate communication of software or data. The term “signal medium” may o include any form of a modulated data signal, carrier wave, and so forth. The term “modulated data signal” means a signal that has one or more of its characteristics set or changed in such a matter as to encode information in the signal. The terms “transmission medium” and “signal medium” mean the same thing and may be used interchangeably in this disclosure.

What is claimed is:

1. A system for analyzing geospatial moving entities, the system comprising:
a memory storing instructions; and
a hardware processor operatively coupled to the memory, the instructions when executed by the hardware processor causing the hardware processor to perform operations comprising:
accessing trajectory data for a plurality of moving entities;
selecting a query moving entity from the plurality of moving entities;
determining a set of trajectories for a set of moving entities in the plurality of moving entities where each single trajectory in the set of trajectories is near a trajectory of the query moving entity;
determining a set of trajectory scores for the set of trajectories, the determining of the set of trajectory scores comprising scoring each individual trajectory in the set of trajectories using a scoring function that evaluates, over multiple observations, co-occurrence of the query moving entity with an individual moving entity associated with the individual trajectory;
determining, from the set of moving entities, a set of co-traveling moving entities that co-travel with the query moving entity, the determining of the set of co-traveling moving entities being based on the set of trajectory scores; and
performing an intelligence analysis based on the set of co-traveling moving entities.

2. The system of claim 1, wherein the query moving entity comprises a rogue ship, and wherein the intelligence analysis comprises identifying one or more other moving entities co-traveling with the rogue ship.

3. The system of claim 1, wherein the determining of the set of trajectories for the set of moving entities comprises:
determining that a select trajectory of a select moving entity in the set of moving entities is near the query moving entity in response to at least one movement of the select trajectory being within a fixed radius from the query moving entity at a given time instance.

4. The system of claim 3, wherein the fixed radius is adjustable based on a moving entity type of the query moving entity.

5. The system of claim 4, wherein the fixed radius is set to 10 km when the query moving entity comprises a ship.

6. The system of claim 4, wherein the fixed radius is set to 0.01° when the query moving entity comprises a transponder.

7. The system of claim 1, wherein the scoring of the individual trajectory in the set of trajectories using the scoring function comprises:
using a non-probabilistic model that calculates a minimum weighted sum squared errors between positions of the query moving entity and the individual moving entity associated with the individual trajectory.

8. The system of claim 7, wherein the non-probabilistic model is configured to apply a weighting factor based on a distance traveled by either the query moving entity or the individual moving entity during a sub-voyage, sub-voyage comprising a time-consecutive subsequence of proximities in a voyage.

9. The system of claim 1, wherein the scoring of the individual trajectory in the set of trajectories using the scoring function comprises:
using a probabilistic model that captures a likelihood of observations about relative directions and speeds of moving entities.

10. The system of claim 9, wherein the probabilistic model is configured to combine observations using an exponential model with one or more features, the one or more features comprising at least one of:
squared error between positions of moving entities;
cosine distance between movement lines of moving entities;
difference between speeds of moving entities; or
speed of moving entities.

11. The system of claim 10, wherein at least one feature of the one or more features follows a Gaussian distribution.

12. The system of claim 9, wherein the probabilistic model is configured to apply a weighting factor that assigns more weight to movements over long time intervals compared to movements over short time intervals.

13. The system of claim 1, wherein the scoring of the individual trajectory in the set of trajectories using the scoring function comprises:
using a hidden semi-Markov model to identify discontiguous co-travels between the query moving entity and the individual moving entity associated with the individual trajectory.

14. The system of claim 13, wherein the hidden semi-Markov model uses a scoring function based on a log-odds ratio of a probability of a most likely state sequence divided by a probability of non-co-travel.

15. The system of claim 1, wherein the operations comprise:
prior to performing the intelligence analysis based on the set of co-traveling moving entities, applying a post-filter to the set of co-traveling moving entities based on one or more of:
rank of trajectories;
distance traveled;
time spent co-traveling; and
score normalized by co-travel time.

16. The system of claim 1, wherein the query moving entity comprises one of a ship, an automotive vehicle, an aircraft, or a transponder.

17. A machine-storage medium comprising instructions that, when executed by a hardware processor of a device, cause the device to perform operations comprising:
accessing trajectory data for a plurality of moving entities;
selecting a query moving entity from the plurality of moving entities;
determining a set of trajectories for a set of moving entities in the plurality of moving entities where each single trajectory in the set of trajectories is near a trajectory of the query moving entity;
determining a set of trajectory scores for the set of trajectories, the determining of the set of trajectory scores comprising scoring each individual trajectory in the set of trajectories using a scoring function that evaluates, over multiple observations, co-occurrence of the query moving entity with an individual moving entity associated with the individual trajectory;
determining, from the set of moving entities, a set of co-traveling moving entities that co-travel with the query moving entity, the determining of the set of co-traveling moving entities being based on the set of trajectory scores; and
performing an intelligence analysis based on the set of co-traveling moving entities.

18. The machine-storage medium of claim 17, wherein the query moving entity comprises a rogue ship, and wherein the intelligence analysis comprises identifying one or more other moving entities co-traveling with the rogue ship.

19. The machine-storage medium of claim 17, wherein the determining of the set of trajectories for the set of moving entities comprises:
determining that a select trajectory of a select moving entity in the set of moving entities is near the query moving entity in response to at least one movement of the select trajectory being within a fixed radius from the query moving entity at a given time instance.

20. A method comprising:
accessing, by one or more hardware processors, trajectory data for a plurality of moving entities;
selecting, by the one or more hardware processors, a query moving entity from the plurality of moving entities;
determining, by the one or more hardware processors, a set of trajectories for a set of moving entities in the plurality of moving entities where each single trajectory in the set of trajectories is near a trajectory of the query moving entity;
determining, by the one or more hardware processors, a set of trajectory scores for the set of trajectories, the determining of the set of trajectory scores comprising scoring each individual trajectory in the set of trajectories using a scoring function that evaluates, over multiple observations, co-occurrence of the query moving entity with an individual moving entity associated with the individual trajectory;
determining, by the one or more hardware processors and from the set of moving entities, a set of co-traveling moving entities that co-travel with the query moving entity, the determining of the set of co-traveling moving entities being based on the set of trajectory scores; and
performing, by the one or more hardware processors, an intelligence analysis based on the set of co-traveling moving entities.
